(19) United States
(12) Patent Application Publication
(10) Pub. No.: US 2016/0226476 A1
(43) Pub. Date: Aug. 4, 2016

(54) DUTY CYCLE DETECTION CIRCUIT AND DUTY CYCLE CORRECTION CIRCUIT INCLUDING THE SAME

(71) Applicant: SK hynix Inc., Gyeonggi-do (KR)

(72) Inventors: Hae-Rang CHOI, Gyeonggi-do (KR); Dae-Han KWON, Gyeonggi-do (KR); Yong-Ju KIM, Gyeonggi-do (KR)

(21) Appl. No.: 14/793,411

(22) Filed: Jul. 7, 2015

(30) Foreign Application Priority Data
Feb. 2, 2015 (KR) 10-2015-0015977

(51) Int. Cl. H03K 9/08

(52) U.S. Cl. CPC H03K 9/08

(57) ABSTRACT

A duty cycle detection circuit includes a reset unit suitable for resetting a first capacitor and a second capacitor based on a reset signal, a first charging/discharging unit suitable for charging the first capacitor while a clock is in a first level and discharging the first capacitor while the clock is in a second level, a second charging/discharging unit suitable for charging the second capacitor while the clock is in the second level and discharging the second capacitor while the clock is in the first level, and a differential amplifier suitable for amplifying a voltage difference between the first capacitor and the second capacitor based on an amplification enable signal and generating a detection signal as a result of the amplification.

### CROSS-REFERENCE TO RELATED APPLICATIONS

The present application claims priority of Korean Patent Application No. 10-2015-0015977, filed on Feb. 2, 2015, which is incorporated herein by reference in its entirety.

### BACKGROUND

1. Field

Exemplary embodiments of the present invention relate to a duty cycle correction (DCC) circuit and, more particularly, to a technology for detecting a duty cycle.

2. Description of the Related Art

Various semiconductor devices, including memory devices, are being developed to have higher capacity, higher speed, and lower power consumption. To increase speed, semiconductor devices are designed to operate in synchronization with a faster clock.

Therefore, the frequency of the semiconductor devices' internal clocks is getting higher. The frequency of internal clocks currently is in the realm of several GHz or more. To accurately operate a semiconductor device in synchronization with a high frequency clock, the clock needs to be very accurate. In other words, if there are many jitter causing components in the clock, making the duty ratio of the clock deviate from 50:50, stable circuit operation may not be achievable because the semiconductor device operation timing will be out of synchronization.

To this end, a DCC circuit for adjusting the duty ratio of a clock to 50:50, that is, for correcting the widths of high and low pulse sections to have a duty ratio of 50:50, is used. For fast and accurate operation of the DCC circuit, the duty cycle needs to be detected fast and accurately.

### SUMMARY

Various embodiments are directed to a duty cycle detection circuit that may operate fast and accurately, and a DCC circuit.

In an embodiment, a duty cycle detection circuit may include a reset unit suitable for resetting a first capacitor and a second capacitor based on a reset signal, a first charging/discharging unit suitable for charging the first capacitor while a clock is in a first level and discharging the first capacitor while the clock is in a second level, a second charging/discharging unit suitable for charging the second capacitor while the clock is in the second level and discharging the second capacitor while the clock is in the first level, and a differential amplifier suitable for amplifying a voltage difference between the first capacitor and the second capacitor based on an amplification enable signal to generate a detection signal.

The amplification enable signal may be activated after a lapse of a predetermined time from when the reset signal may be activated.

In an embodiment, a duty cycle correction circuit may include a duty correction unit suitable for generating an output clock and an inverted output clock by correcting the duty cycle of an input clock and an inverted input clock based on a detection signal, a reset unit suitable for resetting a first capacitor and a second capacitor based on a reset signal, a first charging/discharging unit suitable for charging the first capacitor while a clock is in a first level and discharging the first capacitor while the clock is in a second level, a second charging/discharging unit suitable for charging the second capacitor while the inverted clock is in the first level and discharging the second capacitor while the inverted clock is in the second level, and a differential amplifier suitable for amplifying a voltage difference between the first capacitor and the second capacitor based on an amplification enable signal and generating the detection signal as a result of the amplification.

The amplification enable signal may be activated after a lapse of a predetermined time from when the reset signal may be activated.

In an embodiment, a method for detecting a duty cycle may include resetting a first capacitor and a second capacitor to have the same voltage, charging the first capacitor while a clock is in a first level and discharging the first capacitor while the clock is in a second level, charging the second capacitor while an inverted clock is in the first level and discharging the second capacitor while the inverted clock is in the second level, and generating a detection signal by amplifying a voltage difference between the first capacitor and the second capacitor after the charging and discharging of the first capacitor and the charging and discharging of the second capacitor are performed for a predetermined time.

### BRIEF DESCRIPTION OF THE DRAWINGS

FIG. 1 is a diagram illustrating a duty cycle detection circuit in accordance with an embodiment of the present invention.

FIG. 2 is a timing diagram for describing an operation of the duty cycle detection circuit shown in FIG. 1.

FIG. 3 is a diagram illustrating a DCC circuit in accordance with an embodiment of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts in the various figures and embodiments of the present invention.

The drawings are not necessarily to scale and, in some instances, proportions may have been exaggerated to clearly illustrate features of the embodiments. It is also noted that in this specification, “connected/coupled” refers to one component not only directly coupling another component but also indirectly coupling another component through an intermediate component. In addition, a singular form may include a plural form as long as it is not specifically mentioned in a sentence.

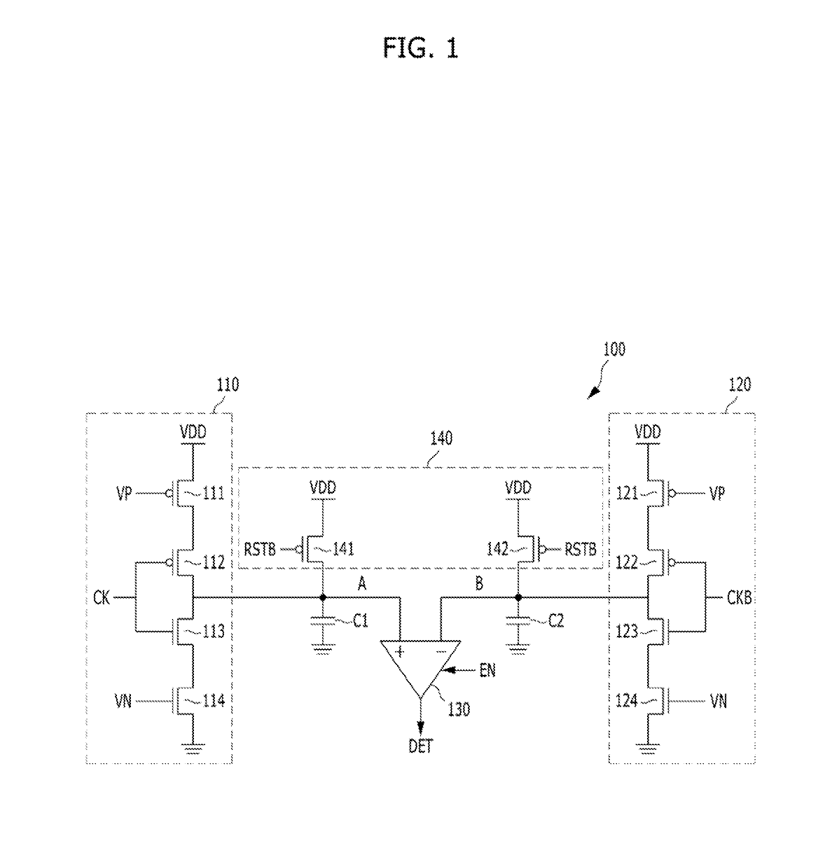

FIG. 1 is a diagram illustrating a duty cycle detection circuit 100 in accordance with an embodiment of the present invention.

Referring to FIG. 1, the duty cycle detection circuit 100 may include a first charging/discharging unit 110, a second charging/discharging unit 120, a differential amplifier 130, a reset unit 140, a first capacitor C1, and a second capacitor C2.

The first capacitor C1 is connected to a first node ‘A’, and the second capacitor C2 is connected to a second node ‘B’.

The reset unit 140 may reset the first node ‘A’ and the second node ‘B’ to have the same voltage in response to a reset signal RSTB. That is, when the reset signal RSTB is activated, the reset unit 140 may reset the voltages of the first capacitor C1 and the second capacitor C2. The reset unit 140 may include PMOS transistors 141 and 142. When the reset signal RSTB is activated to logic “low” level, the first capacitor C1 and the second capacitor C2 may be reset to have a power supply voltage VDD. Since the reset unit 140 may reset the voltages of the first capacitor C1 and the second capacitor C2 quickly, the amount of current of the reset unit 140 may be set to be much greater than that of the first charging/discharging unit 110 and the second charging/discharging unit 120.

The first charging/discharging unit 110 may charge the first node ‘A’, that is, the first capacitor C1, while a clock CK is in a first level (e.g., a logic “low” level) and discharge the first node ‘A’, that is, the first capacitor C1, while the clock CK is in a second level (e.g., a logic “high” level). The first charging/discharging unit 110 may include PMOS transistors 111 and 112 and NMOS transistors 113 and 114. The PMOS transistors 111 and 112 pull-up drives (or charges) the first node ‘A’ and the NMOS transistors 113 and 114 pull-down drives (or discharges) the first node ‘A’. When the clock CK is in a logic “low” level, the PMOS transistor 112 is turned on and thus the first charging/discharging unit 110 may charge the first node ‘A’. When the clock CK is in a logic “high” level, the NMOS transistor 113 is turned on and thus the first charging/discharging unit 110 may discharge the first node ‘A’. A pull-up bias voltage VP is applied to the gate of the PMOS transistor 111, and a pull-down bias voltage VN is applied to the gate of the NMOS transistor 114. The PMOS transistor 111 and the NMOS transistor 114 may function to control the amount of charging current and amount of discharging current of the first charging/discharging unit 110.

The second charging/discharging unit 120 may charge the second node ‘B’, that is, the second capacitor C2, while the clock CK is in the second level and discharge the second node ‘B’, that is, the second capacitor C2, while the clock CK is in the first level. The second charging/discharging unit 120 may operate in response to an inverted clock CKB, that is, a complementary clock of the clock CK. Accordingly, the second charging/discharging unit 120 may charge the second node ‘B’ while the inverted clock CKB is in the first level and discharge the second node ‘B’ while the inverted clock CKB is in the second level. The second charging/discharging unit 120 may include PMOS transistors 121 and 122 and NMOS transistors 123 and 124. The PMOS transistors 121 and 122 pull-up drives (or charges) the second node ‘B’ and the NMOS transistors 123 and 124 pull-down drives (or discharges) the second node ‘B’. When the inverted clock CKB is in a logic “low” level, the PMOS transistor 122 is turned on and thus the second charging/discharging unit 120 may charge the second node ‘B’. When the inverted clock CKB is in a logic “high” level, the NMOS transistor 123 is turned on and thus the second charging/discharging unit 120 may discharge the second node ‘B’. The pull-up bias voltage VP is applied to the gate of the PMOS transistor 121, and the pull-down bias voltage VN is applied to the gate of the NMOS transistor 124. The PMOS transistor 121 and the NMOS transistor 124 may function to control the amount of charging current and amount of discharging current of the second charging/discharging unit 120.

The differential amplifier 130 may amplify a voltage difference between the first node ‘A’ and the second node ‘B’ in response to an amplification enable signal EN and generate a detection signal DET as a result of the amplification. If the first node ‘A’ has a voltage that is higher than the second node ‘B’, the detection signal DET may have a logic “high” level. If the second node ‘B’ has a voltage that is higher than the first node ‘A’, the detection signal DET may have a logic “low” level. If the detection signal DET has a logic “high” level, it may mean that the low pulse width of the clock CK is longer than the high pulse width thereof and the high pulse width of the inverted clock CKB is longer than the low pulse width thereof. In contrast, if the detection signal DET has a logic “low” level, it may mean that the high pulse width of the clock CK is longer than the low pulse width thereof and the low pulse width of the inverted clock CKB is longer than the high pulse width thereof. The amplification enable signal EN may be activated after a lapse of a predetermined time from when the reset signal RSTB is activated.

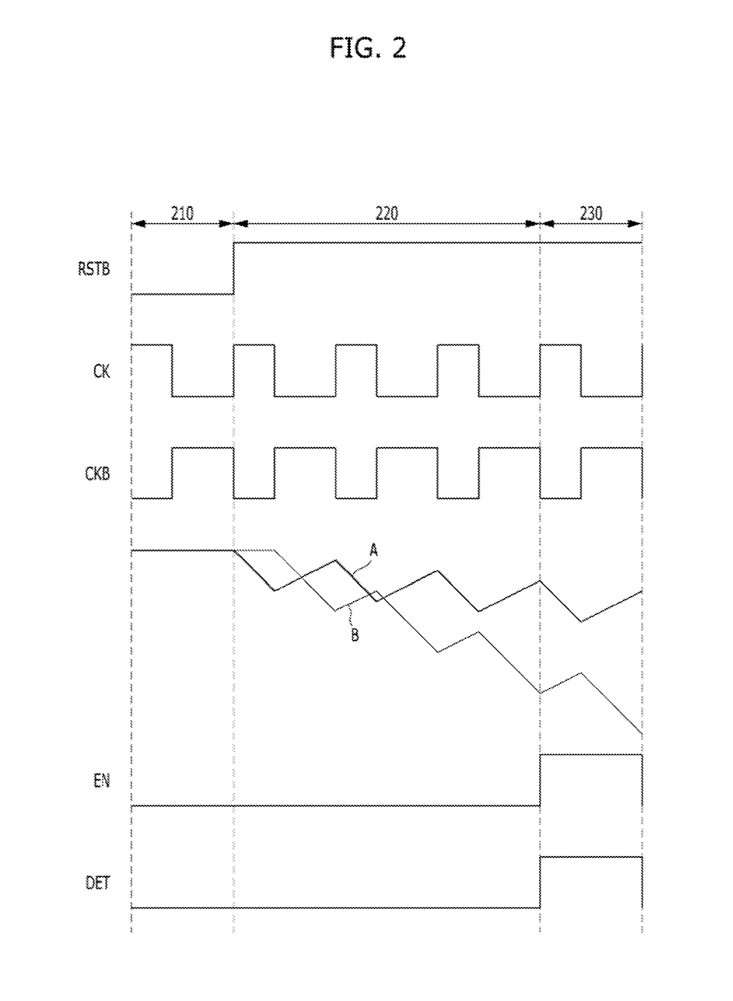

FIG. 2 is a timing diagram for describing an operation of the duty cycle detection circuit 100 shown in FIG. 1.

Referring to FIG. 2, the operation of the duty cycle detection circuit 100 may be divided into a reset section 210, an accumulation section 220, and an amplification section 230.

In the reset section 210, the reset signal RSTB may be activated to logic “low” level, and the reset unit 210 may reset the voltages of the first node ‘A’ and the second node ‘B’ to have the power supply voltage VDD.

In the accumulation section 220, the first charging/discharging unit 110 may repeat an operation for charging and discharging the first node ‘A’ in response to a level of the clock CK. Furthermore, the second charging/discharging unit 120 may repeat an operation for charging and discharging the second node ‘B’ in response to a level of the inverted clock CKB. In FIG. 2, the low pulse width of the clock CK has been illustrated as being longer than the high pulse width thereof, and the high pulse width of the inverted clock CKB is longer than the low pulse width thereof. In this example, as charging and discharging are repeated, a voltage of the first node ‘A’ may be higher than that of the second node ‘B’. In the accumulation section 220, an operation for charging and discharging the first node ‘A’ and the second node ‘B’ is repeated in response to a level of the clock CK and a level of the inverted clock CKB. Accordingly, a voltage difference between the first node ‘A’ and the second node ‘B’ may be increased relatively quick.

In the amplification section 230, the amplification enable signal EN is activated, a voltage difference between the first node ‘A’ and the second node ‘B’ may be amplified by the differential amplifier 130, and the detection signal DET may be generated as a result of the amplification. From FIG. 2, it may be seen that the detection signal DET of a logic “high” level is generated because the first node ‘A’ has a voltage that is higher than the second node ‘B’.

The amplification section 230 enters when the amplification enable signal EN is activated after a voltage difference between the first node ‘A’ and the second node ‘B’ becomes sufficient through the accumulation section 220. Accordingly, the differential amplifier 130 may not malfunction. Duration of the accumulation section 220, that is, the period from when the reset signal RSTB is activated to when the amplification enable signal EN is activated, may be set so that a voltage difference between the first node ‘A’ and the second node ‘B’ is equal to or greater than the offset of the differential amplifier 130 (i.e., a difference between input voltages for stably operating the differential amplifier 130).

In FIG. 2, the duty cycle detection circuit 100 has been illustrated as having one cycle operation for detecting the duty cycle of the clock CK and the inverted clock CKB once (the one cycle operation includes the reset section 210, the accumulation section 220, and the amplification section 230). In some embodiments, the operation of FIG. 2 may be repeated several times, and the duty cycle detection circuit 100 may consecutively detect the duty cycle of the clock CK and the inverted clock CKB several times.

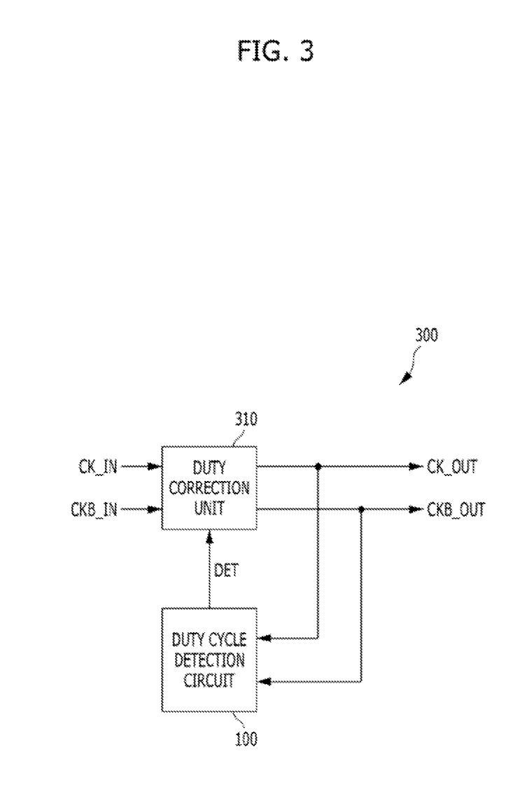

FIG. 3 is a diagram illustrating a DCC circuit 300 in accordance with an embodiment of the present invention.

Referring to FIG. 3, the DCC circuit 300 may include a duty correction unit 310 and a duty cycle detection circuit 100.

The duty cycle detection circuit 100 may generate the detection signal DET by detecting the duty cycle of an output clock CK_OUT and an inverted output clock (i.e., a complementary clock of the output clock CK_OUT) CKB_OUT output by the duty correction unit 310. The duty cycle detection circuit 100 may be configured as in FIG. 2 and may operate as in FIG. 3.

The duty correction unit 310 may generate the output clock CK_OUT and the inverted output clock CKB_OUT by correcting the duty cycle of an input clock CK_IN and an inverted input clock (i.e., a complementary clock of the input clock CK_IN) CKB_IN in response to the detection signal DET. The duty correction unit 310 may control the high pulse widths and low pulse widths of the input clock CK_IN and the inverted input clock CKB_IN in response to the detection signal DET so that the output clock CK_OUT and the inverted output clock CKB_OUT have a duty ratio of 50:50 and generate the output clock CK_OUT and the inverted output clock CK_OUTB.

In accordance with embodiments of the present invention, the duty cycle of a clock may be detected fast and accurately.

Although various embodiments have been described for illustrative purposes, it will be apparent to those skilled in the art that various changes and modifications may be made without departing from the spirit and scope of the invention as defined in the following claims.

What is claimed is:

1. A duty cycle detection circuit comprising:
a reset unit suitable for resetting a first capacitor and a second capacitor based on a reset signal;
a first charging/discharging unit suitable for charging the first capacitor while a clock is in a first level and discharging the first capacitor while the clock is in a second level;
a second charging/discharging unit suitable for charging the second capacitor while the clock is in the second level and discharging the second capacitor while the clock is in the first level; and
a differential amplifier suitable for amplifying a voltage difference between the first capacitor and the second capacitor based on an amplification enable signal to generate a detection signal.

2. The duty cycle detection circuit of claim 1, wherein the amplification enable signal is activated after a predetermined time lapses from when the reset signal is activated.

3. The duty cycle detection circuit of claim 1, wherein the second charging/discharging unit operates based on an inverted clock, charges the second capacitor while the inverted clock is in the first level, and discharges the second capacitor while the inverted clock is in the second level.

4. The duty cycle detection circuit of claim 3, wherein the first charging/discharging unit includes:
a first PMOS transistor receiving a pull-up bias voltage;
a second PMOS transistor receiving the clock;
a first NMOS transistor receiving the clock; and
a first NMOS transistor receiving a pull-down bias voltage.

5. The duty cycle detection circuit of claim 4, wherein the second charging/discharging unit includes:
a third PMOS transistor receiving the pull-up bias voltage;
a fourth PMOS transistor receiving the inverted clock;
a third NMOS transistor receiving the inverted clock; and
a fourth NMOS transistor receiving the pull-down bias voltage.

6. A duty cycle correction circuit, comprising:
a duty correction unit suitable for generating an output clock and an inverted output clock by correcting a duty cycle of an input clock and an inverted input clock based on a detection signal;
a reset unit suitable for resetting a first capacitor and a second capacitor based on a reset signal;
a first charging/discharging unit suitable for charging the first capacitor while a clock is in a first level and discharging the first capacitor while the clock is in a second level;
a second charging/discharging unit suitable for charging the second capacitor while the inverted clock is in the first level and discharging the second capacitor while the inverted clock is in the second level; and
a differential amplifier suitable for amplifying a voltage difference between the first capacitor and the second capacitor based on an amplification enable signal to generate the detection signal.

7. The duty cycle correction circuit of claim 6, wherein the amplification enable signal is activated after a predetermined time lapses from when the reset signal is activated.

8. The duty cycle correction circuit of claim 6, wherein the first charging/discharging unit includes:
a first PMOS transistor receiving a pull-up bias voltage;
a second PMOS transistor receiving the clock;
a first NMOS transistor receiving the clock; and
a first NMOS transistor receiving a pull-down bias voltage.

9. The duty cycle correction circuit of claim 6, wherein the second charging/discharging unit includes:
a third PMOS transistor receiving the pull-up bias voltage;
a fourth PMOS transistor receiving the inverted clock;
a third NMOS transistor receiving the inverted clock; and
a fourth NMOS transistor receiving the pull-down bias voltage.

10. A method for detecting a duty cycle, the method comprising:
resetting a first capacitor and a second capacitor to have an identical voltage;
charging the first capacitor while a clock is in a first level and discharging the first capacitor while the clock is in a second level;
charging the second capacitor while an inverted clock is in the first level and discharging the second capacitor while the inverted clock is in the second level; and
amplifying a voltage difference between the first capacitor and the second capacitor after the charging and discharging of the first and second capacitors are performed for a predetermined time to generate a detection signal.
